(19) United States
(12) Patent Application Publication
(10) Pub. No.: US 2009/0267202 A1
(43) Pub. Date: Oct. 29, 2009

(54) SEMICONDUCTOR PACKAGE

(75) Inventor: CHING-YAO FU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/195,392

(22) Filed: Aug. 20, 2008

(30) Foreign Application Priority Data
Apr. 28, 2008 (CN) 200810301372.2

(51) Int. Cl. H01L 23/495; H01L 21/00

(52) U.S. Cl. 257/670; 438/113; 257/E23.031; 257/E21.001

(57) ABSTRACT

A semiconductor package includes a semiconductor chip, a number of pads, a number of lead bars and an encapsulation material. The semiconductor chip has an upper surface and an opposite bottom surface. Area of the upper surface exceeds that of the bottom surface. The pads are mounted on the upper surface of the semiconductor chip. The lead bars are located around the semiconductor chip and electrically connected with corresponding pads. The encapsulation material covers the semiconductor chip, the pads, the lead bars and the bonding wires.

### BACKGROUND

1. Technical Field

The present invention relates to semiconductor packages and, particularly, to a semiconductor package with improved structural integrity and resistance to separation.

2. Description of Related Art

Bonding wires are often used in semiconductor packages to provide electrical connection between a semiconductor chip and a lead frame. Surfaces of each of these elements are encapsulated in a resin body to prevent exposure to air, with the exception of the bottom of the semiconductor chip. Due to poor adhesion between the side surfaces of the semiconductor chip and the resin body, separation of the two is not uncommon, degrading the performance of the semiconductor package.

Therefore, it is desired to provide a semiconductor package addressing the described shortcomings.

### SUMMARY

An exemplary semiconductor package includes a semiconductor chip, a number of pads, a number of lead bars and an encapsulation material. The semiconductor chip has an upper surface and an opposite bottom surface. The upper surface is exceeds that of the bottom surface. The pads are mounted on the upper surface of the semiconductor chip. The lead bars are located around the semiconductor chip and electrically connected with corresponding pads. The encapsulation material covers the semiconductor chip, the pads, the lead bars and the bonding wires.

Other advantages and novel features will be more readily apparent from the following detailed description set forth below taken in conjunction with the accompanying drawings.

### BRIEF DESCRIPTION OF THE DRAWINGS

FIG. 1 is a schematic view of a semiconductor package according to a first exemplary embodiment.

FIG. 2 is a schematic view of a semiconductor package according to a second exemplary embodiment.

FIG. 3 is a flowchart of a method of packaging the semiconductor package as shown in FIGS. 1, 2.

FIG. 4 is a schematic view of a lead frame used in packaging the semiconductor package as shown in FIGS. 1, 2.

### DETAILED DESCRIPTION OF THE PREFERRED EMBODIMENTS

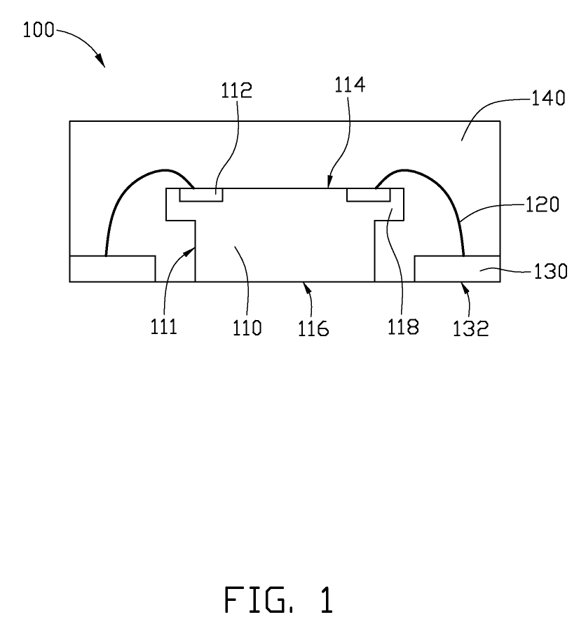

Referring to FIG. 1, a semiconductor package 100 according to an exemplary embodiment includes a semiconductor chip 110, a number of bonding wires 120, a number of lead bars 130, and an encapsulation body 140.

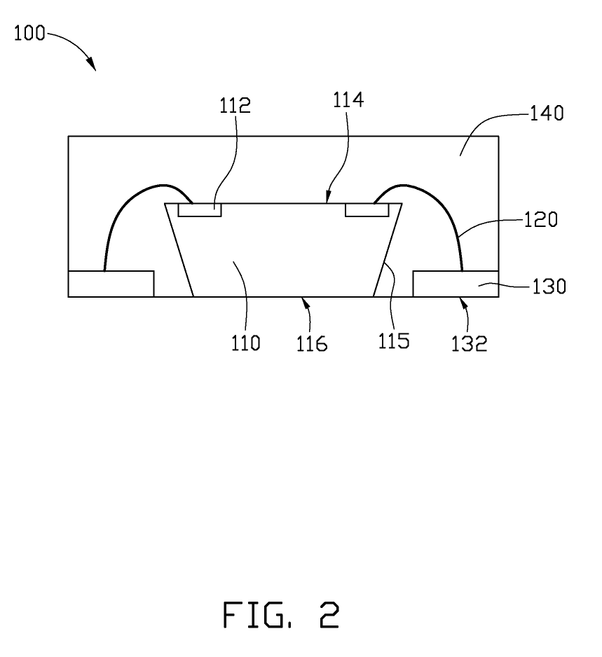

The semiconductor chip 110 may be any type of semiconductor chip known in the art, such as a silicon semiconductor. The semiconductor chip 110 has an upper surface 114, an opposite bottom surface 116 and four side surfaces 111 (only two of which are shown in FIG. 1). The semiconductor chip 110 includes a number of pads 112 outputting signals from the semiconductor chip 110. The pads 112 are respectively mounted on the upper surface 114 of the semiconductor chip 110. In the present embodiment, the semiconductor chip 110 further includes a plurality of flanges 118 protruding from at least two opposite side surfaces 111 along the upper surface 114 of the semiconductor chip 110 as shown in FIG. 1. The flanges 118 can be formed on the four side surfaces 111 of the semiconductor chip 110. Thus, an area of the upper surface 114 exceeds that of the bottom surface 116. Alternatively, the side surfaces 111 of the semiconductor chip 110 can be configured with a gradient profile rather than the flange 118, such that dimensions of the semiconductor chip 110 decrease from the upper surface 112 to the bottom surface 116, forming four inclines 115 therebetween, as shown in FIG. 2.

The lead bars 130 corresponding to the pads 122 of the semiconductor chip 110 positioned surround the semiconductor chip 110. Two ends of each of the bonding wires 120 are respectively connected to the lead bar 130 and the pad 112 by wire bonding technology.

The encapsulation body 140 encapsulates the semiconductor chip 110, the bonding wires 120 and the lead bars 130 therein to prevent exposure to air, while the lower surfaces 132 of the lead bars 130 and the bottom surface 116 of the semiconductor chip 110 are preferably exposed, to allow electrically connection of the semiconductor package 100 to outer circuits and dissipate heat therefrom. With the area of the upper surface 114 exceeding that of the bottom surface 116, the encapsulation body 140 not only adheres to the semiconductor chip 110 but also supports the semiconductor chip 110 through a portion of the upper surface 114 under the flange 118 or the incline 115. Therefore the stability and reliability of the connection between the semiconductor chip 110 and the encapsulation body 140 is improved substantially. It is practical that the area of the upper surface 114 exceed that of the bottom surface 116 of the semiconductor chip 110, creating a portion of the semiconductor chip 100 embeddable in the encapsulation body 140, with resulting enhancement of stability and reliability of the semiconductor package 100.

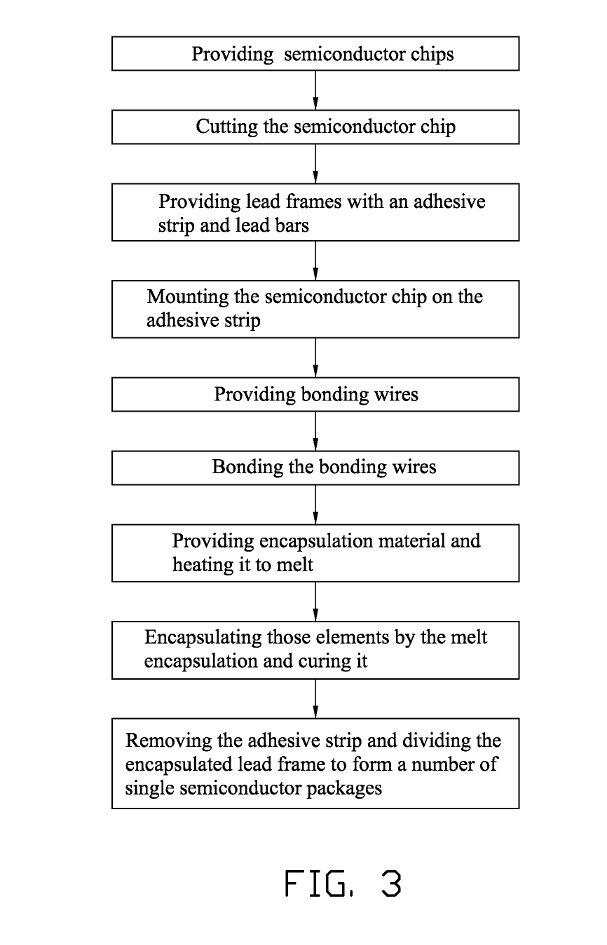

Referring to FIG. 3, a method for packaging the semiconductor package 100 includes the following steps.

A number of semiconductor chips 110 are provided. Each semiconductor chip 110 includes an upper surface 114, an opposite bottom surface, 116 and four side surfaces 111. A number of pads 112 are mounted on the upper surface 114 of the semiconductor chip 110.

A flange 118 or an incline 115 is formed on the side surfaces 111 by cutting off portions of the bottom surface 116 and the side surfaces 111 of the semiconductor chip 110. Area of the upper surface 114 thus exceeds that of the bottom surface 116. As some semiconductor chips 110 have an active layer attached to the upper surface 114, flange 118 must be of sufficient thickness to prevent the damage to the active layer during packaging. That is, flange 118 must be thicker than the active layer. The flange 118 or incline 115 must be symmetrically formed on the semiconductor chip 110 to prevent strain when the semiconductor chip 110 is encapsulated in the encapsulation body 140. Alternatively, the flange 118 or the incline 115 can be formed separately and attached to the side surface 111.

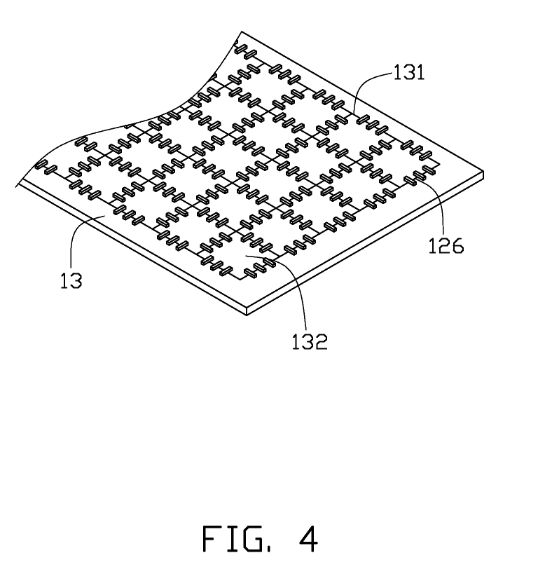

A number of lead frames 135 are provided, as shown in FIG. 4. Each lead frame 135 has a number of bars 130 mounted on an adhesive strip 150. The lead bars 130 are arranged to form a number of receiving portions 137 for semiconductor chips 110. Each receiving portion 137 is equidistantly surrounded by the lead bars 130. The adhesive strip can withstand temperatures such as the melting temperature of the encapsulation body 140.

The semiconductor chips 110 with pads formed thereon are adhered to the adhesive strip 150 via the bottom surface 116 thereof. Semiconductor chips 110 with pads formed thereon are thus situated in the receiving portions 137.

The pads 112 of the semiconductor chips 110 are electrically connected to the corresponding lead bars 130 via bonding wires 120. The bonding wires 120 are gold or copper.

The semiconductor chips 110 and the lead bars 130 are encapsulated by the encapsulation body 140, provided and heated to melt, thereby coating a surface of the adhesive strip 150 to cover the lead frame 135, the semiconductor chips 110 and the lead bars 130 respectively mounted on the surface of the adhesive strip 150 as well as the bonding wires 120 connected between the lead bars 130 and the pads 112 of the semiconductor chip 110. The encapsulation body 140 is epoxide-resin, polyethylene, or other polymer. The adhesive strip 150 is covered on the bottom surfaces 116 of the semiconductor chips 110 and the lower surfaces 132 of the lead bars 130, preventing encapsulation thereof by the encapsulation body 140.

When the melted encapsulation material 140 has cured, the adhesive strip is removed from the semiconductor chips 110 and the lead frame 135, and a number of single semiconductor packages 100 are formed by dividing the encapsulated lead frame 135.

The present invention semiconductor package 100 adopts a semiconductor chip 140 with an upper surface exceeding a bottom surface. As a result, an encapsulation body also supports the semiconductor chip through a portion of the upper surface under a flange or incline. Structural integrity and, commensurately, stability and reliability of the semiconductor chip and encapsulation body, are improved substantially.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A semiconductor package comprising:
a semiconductor chip comprising an upper and opposite bottom surface, area of the upper surface exceeding that of the bottom surface;
a plurality of pads mounted on the upper surface of the semiconductor;
a plurality of lead bars corresponding to the pads located around the semiconductor chip and electrically connected to the pads; and
an encapsulation material covering the semiconductor chip, the pads, and the lead bars.

2. The semiconductor package as claimed in claim 1, wherein the semiconductor chip further comprises a four-sided surface, with two flanges respectively protruding from two opposite side surfaces along the upper surface of the semiconductor chip.

3. The semiconductor package as claimed in claim 1, wherein the semiconductor chip further comprises four side surfaces, with flanges protruding therefrom along the upper surface of the semiconductor chip.

4. The semiconductor package as claimed in claim 1, wherein the semiconductor chip further comprises four side surfaces, and at least two opposite side surfaces of the semiconductor chip are configured with a gradient profile.

5. The semiconductor package as claimed in claim 4, wherein the profile dimensions of the semiconductor chip decreases from the upper surface to the bottom surface, forming an incline between the upper and bottom surfaces.

6. The semiconductor package as claimed in claim 1, wherein the pads of the semiconductor chip and the corresponding lead bars are electrically connected via a plurality of bonding wires.

7. The semiconductor package as claimed in claim 1, wherein the encapsulation material is a type of polymer.

8. The semiconductor package as claimed in claim 1, wherein the polymer is epoxide-resin or polyethylene.

9. The semiconductor package as claimed in claim 2, wherein the semiconductor chip has an active layer attached on the upper surface, than which the flange is thicker.

10. The semiconductor package as claimed in claim 2, wherein the flanges are symmetrically formed on the side surfaces of the semiconductor chip.

11. The semiconductor package as claimed in claim 5, wherein the inclines are symmetrically formed between the upper surface and bottom surface of the semiconductor chip.

12. The semiconductor package as claimed in claim 1, wherein each of the lead bars has a lower surface, and the bottom surface of the semiconductor chip and the lower surface of the lead bars are exposed from the encapsulation material.

13. A packaging method of a semiconductor package, including:
providing a plurality of semiconductor chips, each semiconductor chip comprising an upper surface, an opposite bottom surface and four side surfaces, and a plurality of pads mounted on the upper surface of the semiconductor chip;
forming the upper surface with an area exceeding that of the bottom surface of the semiconductor chip;
providing a plurality of lead frames comprising a plurality of lead bars mounted on an adhesive strip, wherein the lead bars are arranged to form a plurality of receiving portions;
placing the semiconductor chips in receiving portions, respectively, the semiconductor chip adhering on the adhesive strip via the bottom surface thereof;
electrically connecting the pads and the corresponding lead bars;
heating an encapsulation material to melt and coat the lead frames, the semiconductor chips and the lead bars mounted on the surface of the adhesive strip;
removing the adhesive strip from the semiconductor chips and the lead frames; and dividing the encapsulated lead frame to form a plurality of single semiconductor packages when the melted encapsulation material has cured.

14. The packaging method as claimed in claim 13, wherein forming the area of the upper surface to exceed that of the bottom surface of the semiconductor chip includes forming at least two flanges on the side surfaces of the semiconductor chip by cutting off portions of the bottom surface and the side surfaces of the semiconductor chip.

15. The packaging method as claimed in claim 14, wherein the flanges are symmetrically formed on the side surfaces of the semiconductor chip.

16. The packaging method as claimed in claim 14, wherein each semiconductor chip comprises an active layer attached on the upper surface, and the flange is thicker than the active layer.

17. The packaging method as claimed in claim 13, wherein the pads are electrically connected to the corresponding lead bars by a plurality of bonding wires and the bonding wires are covered by the melted encapsulation material.

18. The packaging method as claimed in claim 13, wherein two flanges are formed separately and attached to the side surface adhesively such that the upper surface is larger than the bottom surface of the semiconductor chip.

19. The packaging method as claimed in claim 13, wherein forming the upper surface to exceeds the bottom surface of the semiconductor chip comprises forming at least two inclines on the side surfaces of the semiconductor chip by cutting off portions of the bottom surface and the side surfaces of the semiconductor chip.
